(19) United States
(12) Patent Application Publication
(10) Pub. No.: US 2017/0358520 A1
(43) Pub. Date: Dec. 14, 2017

(54) CHIP-ON-FILM PACKAGE AND DISPLAY DEVICE INCLUDING THE SAME

(71) Applicant: SAMSUNG DISPLAY CO., LTD., YONGIN-SI (KR)

(72) Inventors: Sang Hyeon SONG, Seoul (KR); Byoung Yong KIM, Seoul (KR); Jeong Ho HWANG, Cheonan-si (KR)

(21) Appl. No.: 15/600,849

(22) Filed: May 22, 2017

(30) Foreign Application Priority Data
Jun. 10, 2016 (KR) 10-2016-0072653

(51) Int. Cl. H01L 23/498; G02F 1/133; G09G 3/3208; H01L 23/495

(52) U.S. Cl. CPC H01L 23/4985; H01L 23/49565; G02F 1/133; G09G 3/3208; H01L 23/49838; H01L 23/49572

(57) ABSTRACT

A chip-on-film (COF) package includes a film, a driver integrated circuit (IC) chip disposed on the film, an electrode pad disposed on an edge of the film, and a first deformation-preventing member disposed on the film, between the driver IC chip and the electrode pad.

### CROSS-REFERENCE TO RELATED APPLICATION

This application claims priority under 35 U.S.C. §119 to Korean Patent Application No. 10-2016-0072653, filed in the Korean Intellectual Property Office on Jun. 10, 2016, the disclosure of which is incorporated by reference herein in its entirety.

### TECHNICAL FIELD

The present invention relates to a chip-on-film (COF) package, and more particularly, to a COF package and a display device including the COF package.

### DISCUSSION OF THE RELATED ART

A display device may be used to display an image. A display device may use a liquid crystal display, an organic light-emitting diode display, or the like, to display the image. Display devices that can be bent or folded are being developed.

A bendable or foldable display device includes a display panel, the display panel including a plurality of pixels, and a driver supplying signals to the plurality of pixels. The display panel may include a plurality of gate lines and a plurality of data lines. Each pixel is connected to a gate line and a data line to receive signals. The gate lines transmit gate signals from a gate driver, and the data lines transmit data signals from a data driver.

The gate and data drivers may be embodied as integrated circuit (IC) chips, and the IC chips may be mounted on a film to create a chip-on-film (COF) package. In a process of attaching the IC chips to the film, the film may be bent and/or deformed without damage.

### SUMMARY

According to an exemplary embodiment of the present invention, a chip-on-film (COF) package includes a film, a driver integrated circuit (IC) chip disposed on the film, an electrode pad disposed on an edge of the film, and a first deformation-preventing member disposed on the film, between the driver IC chip and the electrode pad.

According to an exemplary embodiment of the present invention, a COF package includes a film including a first low-elasticity region, a second low-elasticity region, and a high-elasticity region disposed between the first low-elasticity region and the second low-elasticity region, a driver IC chip disposed on the first low-elasticity region of the film, and an electrode pad disposed on the second low-elasticity region of the film. The high-elasticity region has a higher elastic coefficient than the first low-elasticity region and the second low-elasticity region.

According to an exemplary embodiment of the present invention, a display device includes a display panel, and a COF package connected to an edge of the display panel. The COF package includes a film, driver IC chip disposed on the film, an electrode pad disposed on an edge of the film, and a first deformation-preventing member disposed on the film, between the driver IC chip and the electrode pad.

According to an exemplary embodiment of the present invention, a COF package includes a film, a driver IC chip mounted on the film, an electrode pad disposed on an edge of the film, and a deformation-preventing member disposed on the film, between the driver IC chip and the electrode pad. The deformation-preventing member is a stiffener that reduces bending or warping of the film.

### BRIEF DESCRIPTION OF THE DRAWINGS

The above and other features of the present invention will become more apparent by describing in detail exemplary embodiments thereof in conjunction with the accompanying drawings, in which:

FIG. 1 is a top plan view illustrating a display device according to an exemplary embodiment of the present invention;

FIG. 2 is a top plan view illustrating a chip-on-film (COF) package of a display device according to an exemplary embodiment of the present invention;

FIG. 3 is a cross-sectional view taken along line of FIG. 2;

FIG. 4 is a top plan view illustrating a COF package of a display device according to an exemplary embodiment of the present invention;

FIG. 5 is a top plan view illustrating a COF package of a display device according to an exemplary embodiment of the present invention;

FIG. 6 is a top plan view illustrating a COF package of a display device according to an exemplary embodiment of the present invention;

FIG. 7 is a cross-sectional view illustrating a COF package of a display device according to an exemplary embodiment of the present invention;

FIG. 8 is a cross-sectional view illustrating a COF package of a display device according to an exemplary embodiment of the present invention;

FIG. 9 is a top plan view illustrating a COF package of a display device according to an exemplary embodiment of the present invention;

FIG. 10 is a top plan view illustrating a COF package of a display device according to an exemplary embodiment of the present invention; and

FIG. 11 is a cross-sectional view illustrating a COF package of a display device according to an exemplary embodiment of the present invention.

### DETAILED DESCRIPTION OF THE EMBODIMENTS

Hereinafter, the present invention will be described more fully with reference to the accompanying drawings. The described embodiments may be modified in different ways without departing from the spirit and scope of the present invention.

Like reference numerals may refer to like elements throughout the specification. The layers and/or elements in the drawings may be exaggerated for clarity.

When a layer or element is referred to as being on another layer or element, the layer or element may be directly disposed on the other layer or element, or intervening layers or elements may be present therebetween.

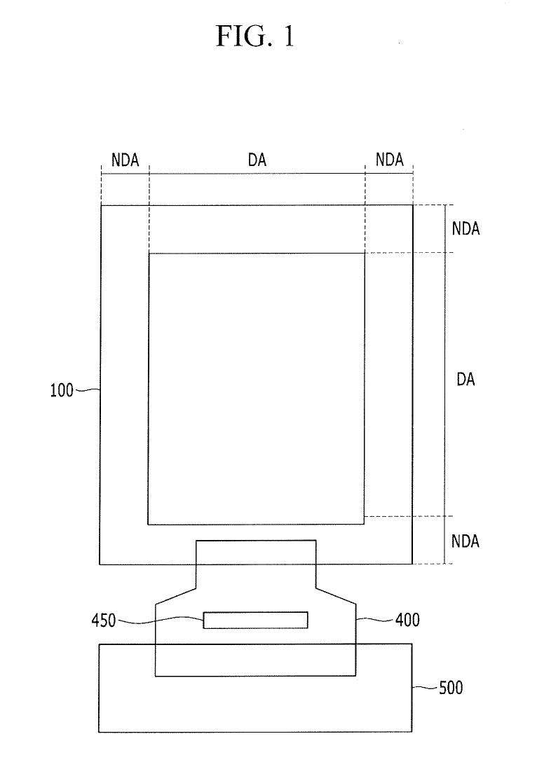

FIG. 1 is a top plan view illustrating a display device according to an exemplary embodiment of the present invention.

As shown in FIG. 1, a display device includes a display panel 100, a chip-on-film (COF) package 400 attached to an edge of the display panel 100, and a printed circuit board (PCB) 500 attached to an edge of the COF package 400.

The display panel 100 may be a liquid crystal panel, an organic light-emitting diode panel, or the like. The display panel 100 includes a display area DA and a non-display area NDA. The non-display area NDA may be disposed at an edge or border of the display panel 100. In FIG. 1, the non-display area NDA has a shape which frames the display area DA. For example, the non-display area NDA has a rectangular shape which is disposed along the entire border of the display area DA. However, the present invention is not limited to this particular shape or configuration of the non-display area NDA. For example, the non-display area NDA may be disposed on one or two edges of the display area DA.

A plurality of pixels may be disposed in the display area DA of the display panel 100. The plurality of pixels may be arranged in a matrix shape. The plurality of pixels may be connected to gate lines and data lines of the display device. Accordingly, the plurality of pixels may receive signals through the gate lines and data lines.

A COF package 400 may be attached to the non-display area DA of the display panel 100. In FIG. 1, the COF package 400 is attached to the lower edge of the display panel 100. However, the present invention is not limited thereto, and the COF package 400 may be attached to other edges of the display panel 100.

A driver integrated circuit (IC) chip 450 may be attached to the COF package 400. The driver IC chip 450 may transmit the signals to the display area DA of the display panel 100 to drive the plurality of pixels. The driver IC chip 450 may include a data driver. The data driver may generate data signals to be transmitted to the data lines. In addition, the driver IC chip 450 may include a gate driver. The gate driver may generate gate signals to be transmitted to the gate lines. However, the gate driver may also be formed as an amorphous silicon gate (ASG), and the ASG may be disposed in the non-display area DA of the display panel 100.

The PCB 500 may generate a plurality of signals for driving the plurality of pixels in the display area DA of the display panel 100. For example, a timing controller may be disposed in the PCB 500, and the timing controller may generate a driving signal for driving the plurality of pixels. The PCB 500 is connected to the COF package 400.

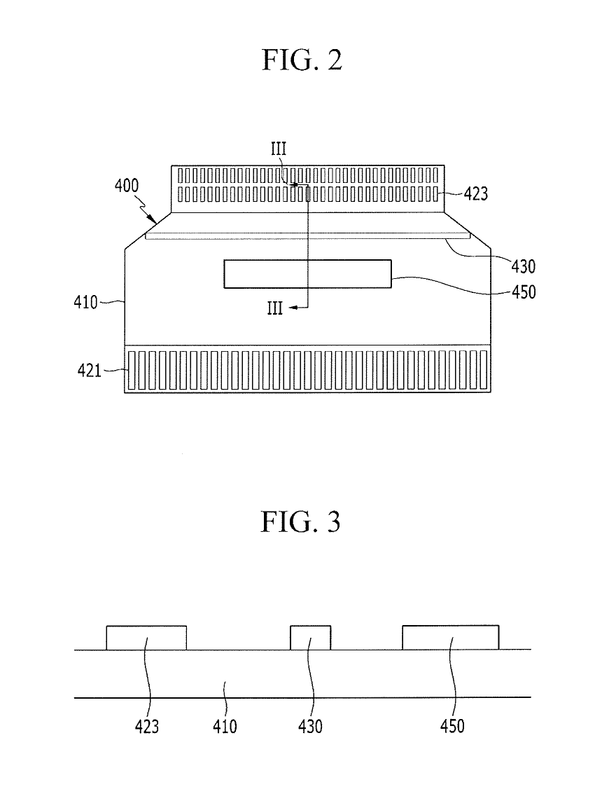

FIG. 2 is a top plan view illustrating a COF package of a display device according to an exemplary embodiment of the present invention. FIG. 3 is a cross-sectional view taken along line of FIG. 2.

The COF package 400 of a display device may include a film 410, a driver IC chip 450 and an output electrode pad 423 disposed on the film 410, and a deformation-preventing member 430 disposed between the driver IC chip 450 and the output electrode pad 423. The film 410 may include a plurality of output electrode pads 423. The deformation-preventing member 430 may be used as a stiffener that reduces deformation, bending or warping of the film 410.

The film 410 may include a thin material that might not be easily bent.

The driver IC chip 450 may be disposed on a central region of the film 410. The driver IC chip 450 may have a rectangular shape that is elongated in a horizontal (e.g., first) direction.

The output electrode pad 423 may be disposed on an edge of the film 410. For example, the output electrode pad 423 may be disposed on an upper edge of an upper surface of the film 410, as shown in FIG. 3. The output electrode pad 423 may overlap the non-display area NDA of the display panel 100 and may be connected to a pad of the display panel. An anisotropic conductive film (ACF) may be disposed between the output electrode pad 423 and the display panel 100. The anisotropic conductive film may conduct electricity only along a thickness direction of the film 410 (e.g., between the film 410 and the output electrode pad 423). The anisotropic conductive film may electrically connect the output electrode pad 423 with the pad of the display panel 100.

The deformation-preventing member 430 may be disposed on the film 410, for example, between the driver IC chip 450 and the output electrode pad 423. The deformation-preventing member 430 may have a bar shape. The deformation-preventing member 430 may extend in a direction parallel to the driver IC chip 450. For example, the deformation-preventing member 430 may have a bar shape that is elongated in the horizontal (e.g., first) direction. A thickness of the deformation-preventing member 430 may be in a range of about 0.1 mm to about 5 mm. A width of the deformation-preventing member 430 may be in a range of about 0.1 mm to about 5 mm. For example, in an exemplary embodiment of the present invention, the width and the thickness of the deformation-preventing member may be about 1 mm each.

The deformation-preventing member 430 includes a hardener. The deformation-preventing member 430 may be formed by coating the hardener, in a liquid form, on the film 410 by using a dispenser and hardening the liquid hardener. After forming the deformation-preventing member 430 on the film 410, the driver IC chip 450 may be attached to the film 410. The process of attaching the driver IC chip 450 to the film 410 may be performed at a high temperature and a high pressure such that the film 410 may be deformed, bent or warped. In an exemplary embodiment of the present invention, the deformation-preventing member 430 is disposed between the driver IC chip 450 and the output electrode pad 423 to increase the strength of the film 410. Accordingly, when attaching the driver IC chip 450 to the film at a high temperature and a high pressure, the deformation-preventing member 430 may prevent the film 410 from becoming deformed, bent or warped.

The hardener may include an ultraviolet (UV) hardener, a room temperature hardener, or the like. When using a UV hardener, the UV hardener is hardened by being exposed to ultraviolet rays, and the room temperature hardener is hardened after a predetermined waiting time at room temperature. The room temperature hardener may be, for example, SE4900, SE9168, or SE9186 of the DOW CORNING CORPORATION, or DP100 or DP420 of the 3M CORPORATION. The UV hardener may be, for example, A700 or A785 of the SEKISUI CORPORATION, or HC-601Z, HC-602S, or HC-603Z of the HANSOL CHEMICAL CORPORATION.

Next, a change in a bending amount of a film 410 before and after attaching a driver IC chip 450 to a COF package 400 will be described with reference to Table 1. The bending amount will be shown for a film 410 including a deformation-preventing member 430, and for a film 410 that does not include a deformation-preventing member 430.

The bending amount of the film 410 is used to measure a change in the thickness of the film 410 with reference to a flat state of the film 410.

TABLE 1

| | | Bending amount of film 410 after | |
|---|---|---|---|
| | | attachment of a driver IC chip 450 | |
| | Pre-existing bending | Case without a | Case with a |
| | amount of film 410 | deformation- | deformation- |
| | before attachment of a | preventing | preventing |
| | driver IC chip 450 | member 430 | member 430 |
| | (μm) | (μm) | (μm) |
| Case #1 | 9.1 | 22.8 | 11 |
| Case #2 | 11.4 | 20.0 | 8.1 |
| Case #3 | 5.5 | 21.0 | 22.1 |

Referring to Table 1, the film 410 has a bending amount of about 5 μm to about 11 μm before the attachment of the driver IC chip 450. When the driver IC chip 450 is attached to the COF package 400 without the deformation-preventing member 430, the film 410 has a bending amount of about 20 μm to about 23 μm. Accordingly, the bending amount of the film 410 increases in the process of attaching the driver IC chip 450.

The deformation of the film 410 is reduced in the case of the COF package 400 formed with the deformation-preventing member 430, when compared with the COP package 400 that excludes the deformation-preventing member 430. Case #1 uses HC-601Z as the deformation-preventing member 430, Case #2 uses HC-602S as the deformation-preventing member 430, and Case #3 uses SE9168 as the deformation-preventing member 430. As can be seen in Table 1, the prevention of the deformation of the film 410 is large when using HC-601Z and HC-602S.

The COF package 400 may further include an input electrode pad 421. The input electrode pad 421 may be disposed on an edge of the film 410. The film 410 may include a plurality of input electrode pads 421. The input electrode pad 421 may be disposed on an edge of the film 410 opposite to the edge where the output electrode pad 423 is disposed. For example, the input electrode pad 421 may be disposed on a lower edge of the film 410. The input electrode pad 421 is connected to the PCB 500. The anisotropic conductive film may also be disposed between the input electrode pad 421 and the PCB 500.

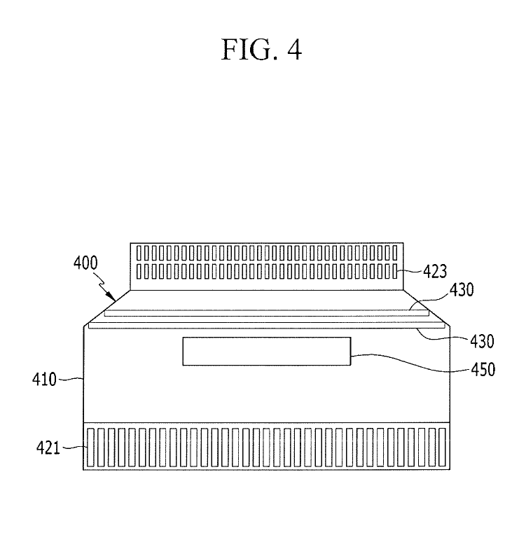

FIG. 4 is a top plan view illustrating a COF package of a display device according to an exemplary embodiment of the present invention.

The COF package 400 of FIG. 4 may include a plurality of deformation-preventing members 430.

Referring to FIG. 4, the COF package 400 includes the film 410, the driver IC chip 450 and the output electrode pad 423 disposed on the film 410, and a plurality of deformation-preventing members 430 disposed between the driver IC chip 450 and the output electrode pad 423.

Two deformation-preventing members 430 may be disposed between the driver IC chip 450 and the output electrode pad 423. The two deformation-preventing members 430 may each have a bar shape and may extend parallel to each other. The two deformation-preventing members 430 may each extend in a direction parallel to the driver IC chip 450.

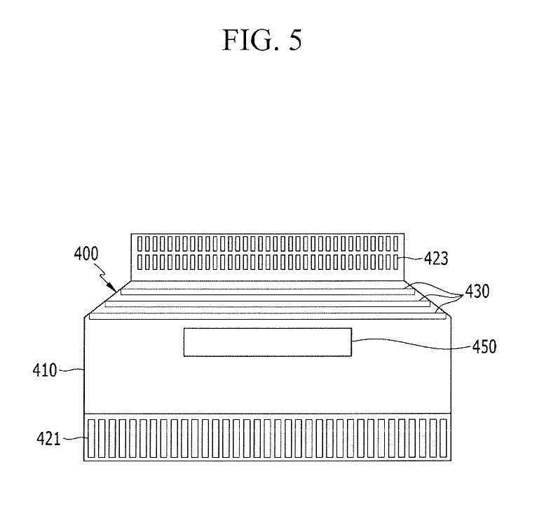

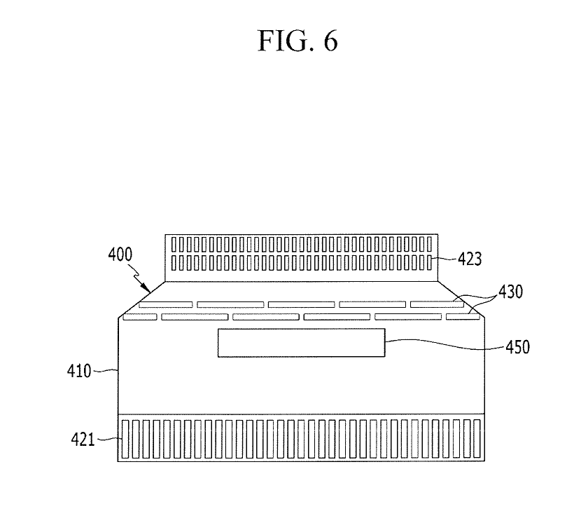

FIG. 5 is a top plan view illustrating a COF package of a display device according to an exemplary embodiment of the present invention. FIG. 6 is a top plan view illustrating a COF package of a display device according to an exemplary embodiment of the present invention.

In FIG. 4, two deformation-preventing members 430 are disposed between the driver IC chip 450 and the output electrode pad 423. However, the present invention is not limited thereto. For example, two or more deformation-preventing members 430 may be disposed between the driver IC chip 450 and the output electrode pad 423. As shown in FIG. 5, three deformation-preventing members 430 may be disposed between the driver IC chip 450 and the output electrode pad 423. Furthermore, four or more deformation preventing members 430 may be positioned between the driver IC chip 450 and the output electrode pad unit 423.

In FIG. 2, FIG. 4, and FIG. 5, each deformation-preventing member 430 has a length corresponding to the width of the film 410 at the location where the deformation-preventing member 430 is formed. However the present invention is not limited thereto. For example, as shown in FIG. 6, a plurality of deformation-preventing members 430, each having a shorter length than the width of the film 410, may be disposed to extend along a same direction (e.g., along a first direction) and may be separated from each other by a predetermined distance along the first direction. In the exemplary embodiments of FIG. 2, FIG. 4, and FIG. 5, the liquid hardener may be coated in a solid line shape to form the deformation-preventing member 430, while in the exemplary embodiment of FIG. 6, the liquid hardener is coated in a dotted line shape to form the deformation-preventing member 430. For example, in the exemplary embodiment of FIG. 6, a process of alternately discharging and stopping the discharging process of the liquid hardener at predetermined times, while moving the dispenser, may be repeatedly performed.

In FIG. 6, the deformation-preventing members 430 are disposed along two parallel imaginary lines. However, a distance by which the imaginary lines are separated from each other may vary. For example, the two imaginary lines may cross each other. Accordingly, the two deformation-preventing members 430 may cross each other.

In FIG. 6, the deformation-preventing members 430 have a dotted line shape and are substantially parallel to each other. However, the present invention is not limited thereto. For example, one or more deformation-preventing members 430 may be disposed on the film 410, and each of the one or more deformation-preventing members 430 may have a dotted line shape. Further, when there are two or more deformation-preventing members 430, the deformation-preventing members 430 may cross each other or may be parallel to each other, regardless of whether the two or more deformation-preventing members 430 have a continuous line shape or a dotted line shape.

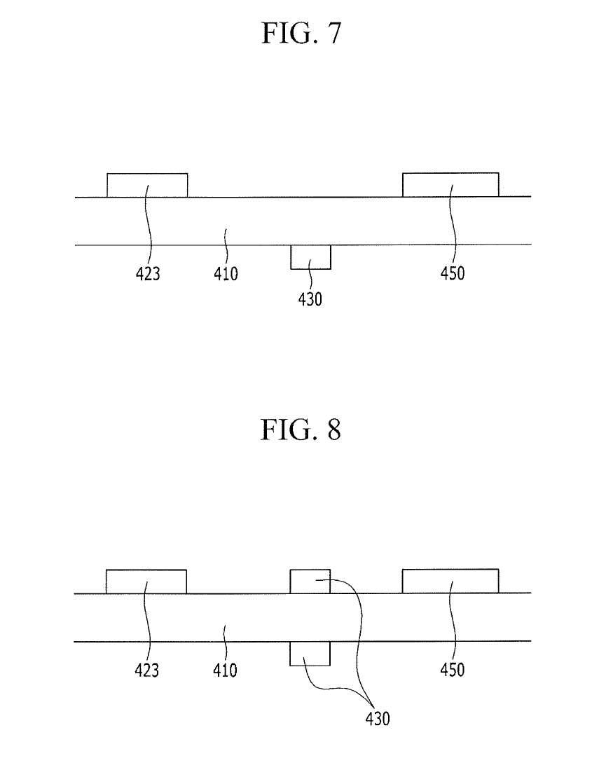

FIG. 7 is a cross-sectional view illustrating a COF package of a display device according to an exemplary embodiment of the present invention.

In the COF package 400 of FIG. 7, the deformation-preventing member may be disposed on the lower surface of the film 410.

The COF package 400 of FIG. 7 includes the deformation-preventing member 430 disposed between the driver IC chip 450 and the output electrode pad 423. In FIG. 7, the deformation-preventing member 430 is disposed on a first surface of the film 410, the first surface of the film 450 being opposite to a second surface of the film 410. The driver IC chip 450 and the output electrode pad 423 are disposed on the second surface of the film 450. The first surface of the film 410 may also be referred to as a lower surface of the film 410. The second surface of the film 410 may also be referred to as an upper surface of the film 410.

FIG. 8 is a cross-sectional view illustrating a COF package of a display device according to an exemplary embodiment of the present invention.

The COF package 400 of FIG. 8 may include a deformation-preventing member 430 on each of the first and second surface of the film 410. For example, the COF package 400 of FIG. 8 may include a deformation-preventing member 430 on both the lower and upper surfaces of the film 410.

The COF package 400 of FIG. 8 includes the deformation-preventing member 430 disposed between the driver IC chip 450 and the output electrode pad 423. In the COF package 400 of FIG. 8, a deformation-preventing member 430 is disposed on the lower surface of the film 410, and a deformation-preventing member 430 is disposed on the upper surface of the film 410. For example, as shown in FIG. 8, the driver IC chip 450 and the output electrode pad 423 are disposed on the upper surface of the film 410, and the deformation-preventing members 430 may respectively overlap the upper surface and the lower surface of the film 410. In this case, the deformation-preventing members 430 may also overlap each other.

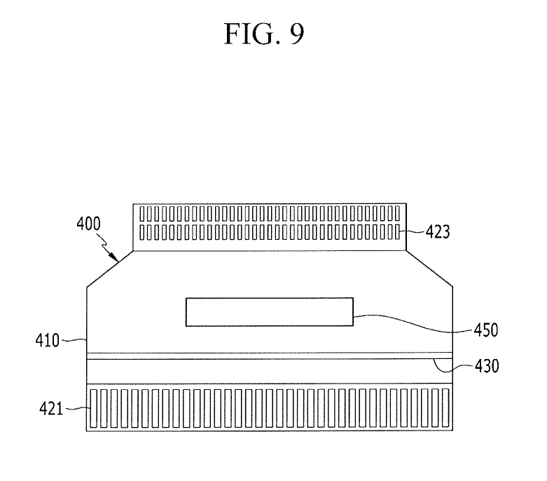

FIG. 9 is a top plan view illustrating a COF package of a display device according to an exemplary embodiment of the present invention.

The COF package 400 of FIG. 9 includes a deformation-preventing member 430 disposed between the driver IC chip 450, and the input electrode pad 421.

The COF package 400 of FIG. 9 includes the film 410, the driver IC chip 450, the output electrode pad 423, and the input electrode pad 421 disposed on the film 410, and the deformation-preventing member 430 disposed between the driver IC chip 450 and the input electrode pad 421.

In FIG. 9, the deformation-preventing member 430 is disposed between the driver IC chip 450 and the input electrode pad 421.

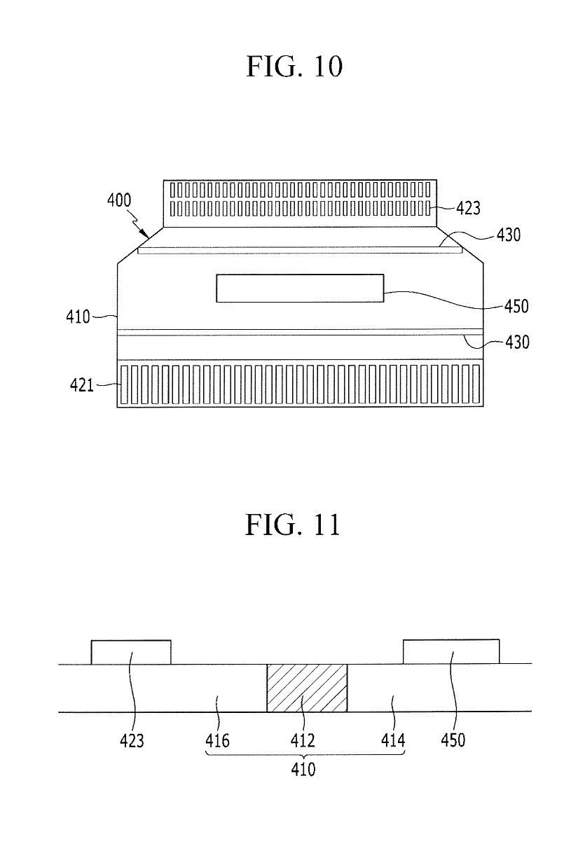

FIG. 10 is a top plan view illustrating a COF package of a display device according to an exemplary embodiment of the present invention.

The COF package 400 of FIG. 10 includes a first deformation-preventing member 430, which is disposed between the driver IC chip 450 and the input electrode pad 421, and a second deformation-preventing member 430, which is disposed between the driver IC chip 450 and the output electrode pad 423.

The COF package 400 of FIG. 10 includes the film 410, the driver IC chip 450, the output electrode pad 423, the input electrode pad 421 disposed on the film 410, a first deformation-preventing member 430 disposed between the driver IC chip 450 and the output electrode pad 423 and a second deformation-preventing member 430 disposed between the driver IC chip 450 and the input electrode pad 421.

Accordingly, in the exemplary embodiment of the present invention described with reference to FIG. 10, a deformation-preventing member 430 is disposed on both sides of the driver IC chip 450. The deformation-preventing members 430 of FIG. 10 may extend along the extending direction of the driver IC chip 450.

FIG. 11 is a cross-sectional view illustrating a COF package of a display device according to an exemplary embodiment of the present invention.

The COF package 400 of FIG. 11 may include a film 410. Different regions of the film 410 may include different materials.

The COF package 400 of FIG. 11 includes the film 410, and the driver IC chip 450 and the output electrode pad 423 disposed on the film 410. In this case, the deformation-preventing member 430 might not be separately formed.

The film 410 includes a first low-elasticity region 414, a second low-elasticity region 416, and a high-elasticity region 412. The high-elasticity region 412 has a higher elastic coefficient than that of the first low-elasticity region 414 and the second low-elasticity region 416. For example, the high-elasticity region 412 may be more flexible or more elastic than the first or second low-elasticity regions 414 and 416. The high-elasticity region 412 may be disposed between the first low-elasticity region 414 and the second low-elasticity region 416.

The driver IC chip 450 may be disposed on the first low-elasticity region 414 of the film 410, and the output electrode pad 423 may be disposed on the second low-elasticity region 416 of the film 410. Accordingly, the high-elasticity region 412 may be disposed between the driver IC chip 450 and the output electrode pad 423. In an exemplary embodiment of the present invention, the high-elasticity region 412 on the film 410 serves the same function as the deformation-preventing member 430. The strength of the film 410 may be partially increased by the high-elasticity region 412 of the film 410. Accordingly, when exposing the film 410 to a high temperature and a high pressure to attach the driver IC chip 450 thereto, the film 410 may be deformed, bent, or warped by a small degree. For example, the deformation, bending or warping of the film 410 at a high temperature and high pressure, when attaching the driver IC chip 450 thereto, may be reduced when including the high-elasticity region 412 between the first and second low-elasticity regions 414 and 416, or when including the deformation-preventing members 430 on the film 410.

While the present invention has been particularly shown and described with reference to exemplary embodiments thereof, it will be apparent to those of ordinary skill in the art that various changes in form and detail may be made therein without departing from the spirit and scope of the present invention.

What is claimed is:

1. A chip-on-film (COF) package, comprising:
a film;
a driver integrated circuit (IC) chip disposed on the film;
an electrode pad disposed on an edge of the film; and
a first deformation-preventing member disposed on the film, between the driver IC chip and the electrode pad.

2. The COF package of claim 1, wherein the first deformation-preventing member includes a hardener.

3. The COF package of claim 2, wherein the hardener includes an ultraviolet (UV) hardener or a room temperature hardener.

4. The COF package of claim 1, wherein the first deformation-preventing member has a bar shape.

5. The COF package of claim 4, wherein the first deformation-preventing member and the driver IC chip extend in a same direction and are parallel to each other.

6. The COF package of claim 4, wherein a width of the first deformation-preventing member is in a range of about 0.1 mm to about 5 mm, and
a thickness of the first deformation-preventing member is in a range of about 0.1 mm to about 5 mm.

7. The COF package of claim 1, further comprising a second deformation-preventing member disposed between the driver IC chip and the electrode pad.

8. The COF package of claim 7, wherein the first and second deformation-preventing members extend in a same direction and are parallel to each other.

9. The COF package of claim 7, wherein both the first and second deformation-preventing members extends along a first direction, and the first and second deformation-preventing members are separated from each other along a second direction crossing the first direction.

10. The COF package of claim 1, wherein the first deformation-preventing member is disposed on an upper surface or a lower surface of the film.

11. A chip-on-film (COF) package, comprising:
a film including a first low-elasticity region, a second low-elasticity region, and a high-elasticity region disposed between the first low-elasticity region and the second low-elasticity region, wherein the high-elasticity region has a higher elastic coefficient than the first low-elasticity region and the second low-elasticity region;
a driver integrated circuit (IC) chip disposed on the first low-elasticity region of the film; and
an electrode pad disposed on the second low-elasticity region of the film.

12. A display device, comprising:
a display panel; and
a chip-on-film (COF) package connected to an edge of the display panel,
wherein the COF package includes:
a film;
a driver integrated circuit (IC) chip disposed on the film;
an electrode pad disposed on an edge of the film; and
a first deformation-preventing member disposed on the film, between the driver IC chip and the electrode pad.

13. The display device of claim 12, wherein the first deformation-preventing member includes a hardener.

14. The display device of claim 13, wherein the hardener includes an ultraviolet (UV) hardener or a room temperature hardener.

15. The display device of claim 12, wherein the first deformation-preventing member has a bar shape.

16. The display device of claim 15, wherein the first deformation-preventing member and the driver IC chip extend in a same direction and are parallel to each other.

17. The display device of claim 12, wherein the electrode pad overlaps an edge of the display panel.

18. The display device of claim 12, further comprising a second deformation-preventing member disposed between the driver IC chip and the electrode pad.

19. The display device of claim 18, wherein both the first and second deformation-preventing members extend in a same direction and are parallel to each other.

20. The display device of claim 12, wherein the deformation-preventing member is disposed on an upper surface or a lower surface of the film.

21. A chip-on-film (COF) package, comprising:
a film;
a driver integrated circuit (IC) chip mounted on the film;
an electrode pad disposed on an edge of the film; and
a deformation-preventing member disposed on the film, between the driver IC chip and the electrode pad,
wherein the deformation-preventing member is a stiffener that reduces bending or warping of the film.
